(19) United States
(12) Patent Application Publication
(10) Pub. No.: US 2026/0361318 A1
(43) Pub. Date: Nov. 12, 2026

(54) APPARATUS USING VARIABLE LENGTH CODE AND METHOD FOR CONTROLLING THE SAME

(71) Applicant: LX Semicon Co., Ltd., Daejeon (KR)

(72) Inventors: JUNG YANG BAE, Daejeon (KR); Tai Hwan Kwon, Daejeon (KR); Yuntae Lee, Daejeon (KR)

(73) Assignee: LX Semicon Co., Ltd., Daejeon (KR)

(21) Appl. No.: 19/658,015

(22) Filed: Apr. 24, 2026

(30) Foreign Application Priority Data
May 7, 2025 (KR) 10-2025-0059015

(51) Int. Cl. H03M 7/42; G06F 1/03; H03M 7/30

(52) U.S. Cl. CPC H03M 7/425; G06F 1/03; H03M 7/6005

(57) ABSTRACT

According to the present invention, a method of controlling an apparatus using a variable-length code algorithm comprises receiving encoded data from an external device, generating a look-up table including address information mapped to the received encoded data, decoded pattern information, and additional information and storing the generated look-up table in a memory.

### CROSS-REFERENCE TO RELATED APPLICATION

This application claims priority to and the benefit of Korean Patent Application No. 10-2025-0059015, filed on May 7, 2025, the disclosure of which is incorporated herein by reference in its entirety.

### BACKGROUND

### 1. Field of the Invention

The embodiments of the present invention may be applied to various apparatuses and methods using variable-length codes. For example, a Huffman code or a canonical Huffman code may be used, but the present invention is not limited thereto.

### 2. Discussion of Related Art

For example, when a Huffman code or a canonical Huffman code is used, a bitstream input through a data buffer is first latched for the maximum code length.

Among the input data, only a meaningful portion of the maximum code length is sampled, and the remaining codes are subjected to packing. The packed data is then input to a look-up table (LUT).

Among decoded data and a code length output from a memory, the code length is latched, and after performing barrel shifting for the next input code, the packing process is repeated.

However, according to the above-described conventional technology, since the received bitstream is decoded through logic to sample meaningful code words, and among address inputs for the maximum code length corresponding to the meaningful code word portion, portions other than the meaningful code word portion are packed with zeros and then input to the look-up table, the memory map of the look-up table is not compact.

In addition, since the process involves sampling and packing the code word, latching the data input, and then inputting it to the look-up table, generation of a decoded output for the data input requires two or more cycles, resulting in a temporal delay as a technical limitation.

### SUMMARY OF THE INVENTION

The present invention is directed to improving the overall processing speed of a system by increasing the decoding speed for compressed codes.

For example, the present invention is directed to implementing a high-speed variable-length lossless code decoder through a memory map configuration different from that of the conventional technology.

According to an aspect of the present invention, there is provided a method of controlling an apparatus using a variable-length code algorithm, which includes: receiving encoded data from an external device; generating a look-up table including address information mapped to the received encoded data, decoded pattern information, and additional information; and storing the generated look-up table in a memory.

The method may further include shifting an incoming bitstream using the additional information of the look-up table stored in the memory and outputting decoded pattern information corresponding to the shifted bitstream.

The additional information may correspond to length information indicating a number of valid data items in the bitstream.

The generating of the look-up table may further include generating a plurality of look-up tables.

The generating of the plurality of look-up tables may further include padding zeros at a front of a list of all data transformed into Huffman codes such that the data is aligned to have the same specific bit length.

The method may further include dividing the list of data aligned to have the same specific bit length into two groups based on a specific criterion.

The specific criterion may correspond to a case in which, in the list of data aligned to have the same specific bit length, a number of zeros in upper bits is equal to a number of zeros in lower bits.

According to an aspect of the present invention, there is provided an apparatus using a variable-length code algorithm, which includes: a receiver that receives encoded data from an external device; a generator that generates a look-up table including address information mapped to the received encoded data, decoded pattern information, and additional information; and a memory that stores the generated look-up table.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a diagram illustrating a Huffman tree;

FIGS. 2A and 2B are diagrams for comparing and explaining a Huffman tree and a canonical Huffman tree;

FIG. 3 is a diagram illustrating a canonical Huffman tree according to an embodiment of the present invention;

FIG. 4 is a diagram illustrating a look-up table stored in a memory of an apparatus according to an embodiment of the present invention;

FIG. 5 is a block diagram including main components of an apparatus according to an embodiment of the present invention;

FIG. 6 is a flowchart illustrating a method of controlling an apparatus according to an embodiment of the present invention;

FIG. 7 is a diagram showing the block diagram shown in FIG. 5 in more detail;

FIG. 8 is a diagram illustrating a process of separating a look-up table into two according to another embodiment of the present invention;

FIG. 9 is a block diagram illustrating a memory shown in FIG. 7 in more detail according to another embodiment of the present invention;

FIG. 10 illustrates length tables of a plurality of look-up tables according to another embodiment of the present invention;

FIGS. 11A to 11C and FIG. 12 are diagrams illustrating a process of generating a plurality of look-up tables, according to another embodiment of the present invention;

FIG. 13 is a diagram illustrating the structure of a canonical Huffman tree used in a decoder according to an embodiment of the present invention;

FIG. 14 is a timing diagram illustrating a decoding operation of a decoder according to an embodiment of the present invention; and

FIGS. 15A and 15B are diagrams for comparing an MCU according to the conventional technology and an MCU to which the decoder according to an embodiment of the present invention is applied.

### DETAILED DESCRIPTION OF EXEMPLARY EMBODIMENTS

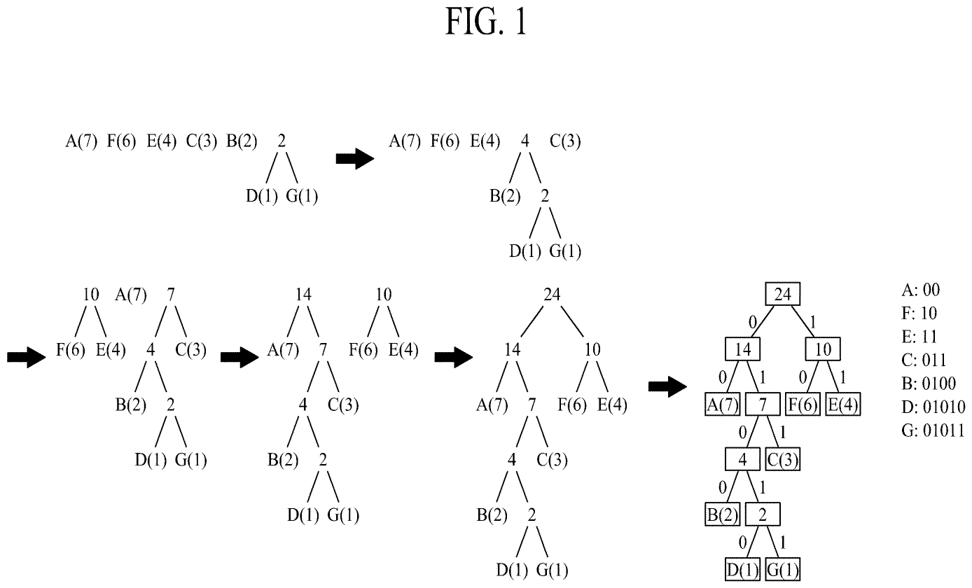

FIG. 1 is a diagram illustrating a Huffman tree.

In the case of a Huffman tree, which is an example of a variable length code (VLC) tree used in lossless compression coding, the frequencies of patterns in a data stream to be compressed are analyzed to assign different code lengths. Patterns with higher frequency are assigned shorter codes, while patterns with lower frequency are assigned longer codes.

The basic structure of a Huffman tree begins with an array of nodes consisting of patterns (frequencies) as shown below:

A(7), F(6), E(4), C(3), B(2), D(1), G(1)

Among the nodes, the two nodes having the smallest and second smallest frequencies are selected, and a new node is generated by combining the frequencies. This process is repeated to construct the tree shown in FIG. 1.

A method of decoding codes using the tree shown in FIG. 1 starts from the root node of the tree, and a node shift is made to the left when the input code bit is 1, and to the right when the input bit is 0, and at the next node, the shift is repeated according to the next bit value, moving left or right accordingly.

At the end of the final node reached, a decoded pattern is present, and decoding is performed by outputting the pattern. However, due to this process, when the code length is long, multiple clock cycles may be required, which is a drawback.

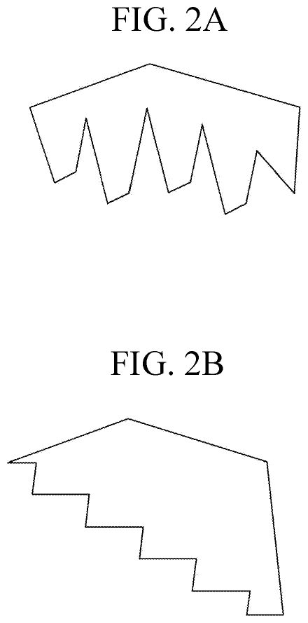

FIGS. 2A and 2B are diagrams for comparing and explaining a Huffman tree and a canonical Huffman tree.

When a Huffman tree is constructed as described with respect to FIG. 1, the tree structure is generated non-uniformly according to the frequencies of each pattern, as shown in FIG. 2A. Because the structure is non-uniform, when decoding is performed using a VLC tree structure, it takes a number of clock cycles corresponding to the code length in proportion to the length of the code to be decoded when the code length is long.

In contrast, when a canonical Huffman tree is used, the tree is reconstructed to have a specific rule based on the code length information assigned to each pattern in the Huffman tree, as shown in FIG. 2B. However, when decoding through tree searching is applied, although not to the extent of the tree shown in FIG. 2A, the possibility that a number of clock cycles may be required to decode a long code may not be completely ruled out.

Accordingly, for VLC decoding, instead of tree searching, a method in which the code length is used as an address input to a look-up table and referenced may be used.

According to an embodiment of the present invention, a decoding method that allows all input codes in a VLC decoding process to be decoded within a single clock cycle (1 cycle clock) by applying a canonical Huffman algorithm and using a look-up table reference method is proposed.

In addition, according to another embodiment of the present invention, additional modification is applied to the memory of the look-up table by utilizing the structural characteristics of the canonical Huffman tree such that the look-up table is split into a plurality of look-up tables. Thus, a method of using a memory more efficiently when using a plurality of look-up tables compared to using a single look-up table is proposed.

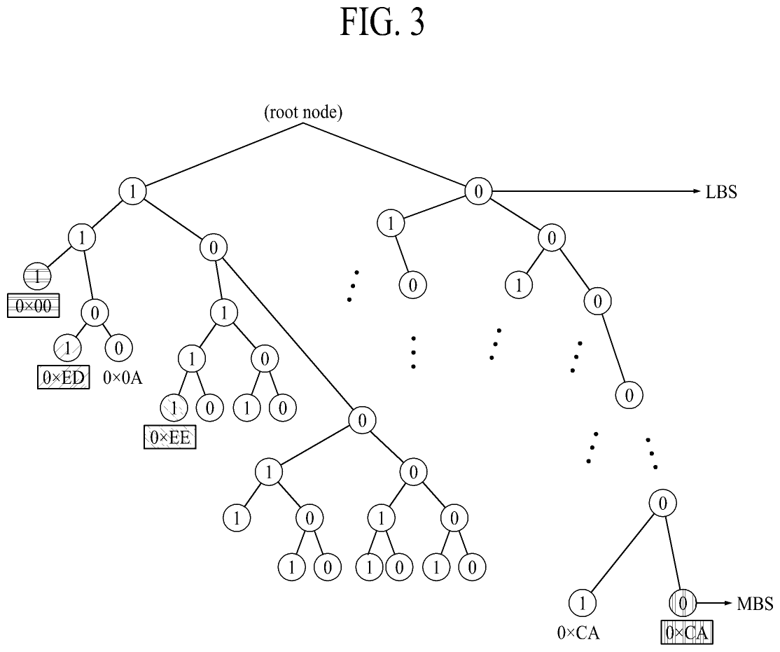

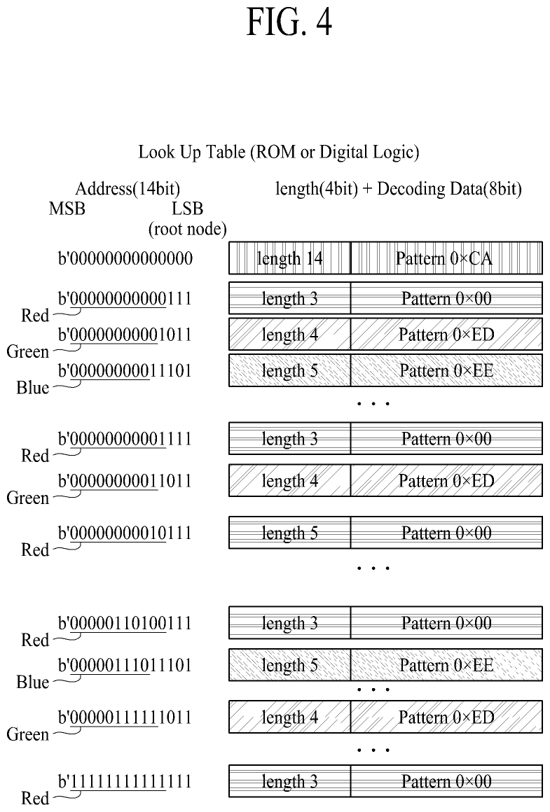

FIG. 3 is a diagram illustrating a canonical Huffman tree according to an embodiment of the present invention. FIG. 4 is a diagram illustrating a look-up table stored in a memory of an apparatus according to an embodiment of the present invention.

In an embodiment of the present invention, the canonical Huffman tree shown in FIG. 3 may be applied. The maximum length is M bits, the minimum length is n bits, and the number of decoded patterns (decoded pattern cases) is k.

The number of target decoded patterns, the maximum code length, and the minimum code length may be adjusted as desired.

For example, the maximum length (Max length) may be 14 bits, the minimum length (min length) may be 3 bits, and the types of decoded patterns may range from 0x00 to 0xFF, although the present invention is not limited thereto.

As shown in FIG. 4, each memory region of the look-up table stores a decoded pattern of a code mapped to the corresponding address and code length information.

The least significant bit (LSB) of the input address of the look-up table may correspond, for example, to the root node of a VLC binary tree.

When the first data of a data input set is directly input to the look-up table in the first cycle, a decoding result is output in the next cycle, and thereafter decoding may be performed in every subsequent cycle.

The bit width of the address input of the look-up table shown in FIG. 4 is assigned according to the maximum code length of the compression algorithm.

As illustrated in FIG. 4, each address of the look-up table according to an embodiment of the present invention includes both a decoded pattern for a code word and code length information of the code.

In other words, a memory map is configured such that decoded patterns for codes input to all addresses containing compressed codes is stored.

For example, when the code word is b′00000000000111 or b′01110100000111 and the value is input to the look-up table, the look-up table outputs, in the next cycle, 0x00 that is the decoded pattern information and 3 that is the code length, which are correspond to the code word “111.”

Thus, regardless of which code is input to the look-up table, the decoded pattern and length information corresponding to a code that matches from the LSB (equivalent to the root node of the VLC binary tree) are output in the next cycle, and barrel shifting is performed using the output code length. Through this process, a code word is output, and the code is decoded in the very next cycle, allowing decoding to be performed in every cycle.

In particular, the difference from the conventional technology will not be described.

When a look-up table is generated using Huffman coding for 8-bit decoded data, typically 256 data items with 14-bit compressed codes are generated.

When the data items are mapped in a memory structure having an address and data configuration, with the code portion as the address and the decoded data matched as the data in a memory, 256 items are valid data, and the remaining entries are filled with invalid (0x00) data.

Due to the sequence in which the initial data input is entered into the buffer and latched, and then the code word is sampled and packed before being input to the look-up table, at least two cycles are required to complete decoding of the initial data.

Among all address inputs to the look-up table, invalid codes undergo a separate packing process before being input to the look-up table.

As a result, in the look-up table, data is present only for the packed addresses, leaving many unused regions of the memory.

In contrast, when using the look-up table shown in FIG. 4 according to an embodiment of the present invention, the lower M bits (e.g., 14 bits) of the initial data input L bits (e.g., 128 bits) may be input directly to the look-up table without a separate latching process, allowing data output within a single cycle.

For the address inputs to the look-up table, decoding results are output upon memory input without requiring separate packing or decoding processes through shifting only.

In all addresses within the look-up table, decoded data and code length of the code mapped to the address are present.

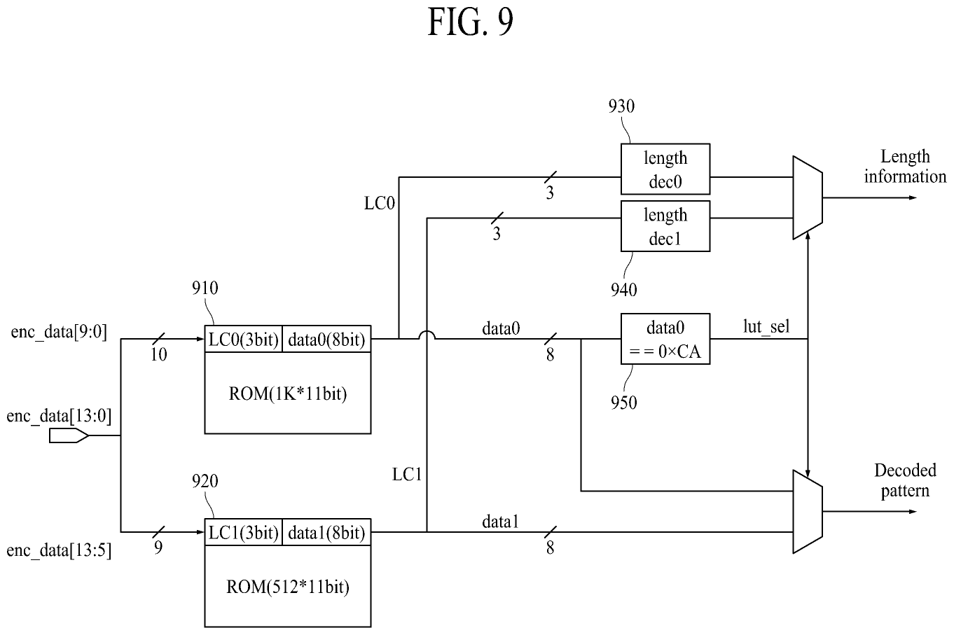

Meanwhile, according to another embodiment of the present invention, due to the characteristics of the canonical Huffman tree, the look-up table may be split into a plurality of look-up tables. Therefore, the area occupied by the look-up table in a memory may be reduced. More detailed embodiments relating to the configuration will be described below with reference to FIG. 8 and other drawings.

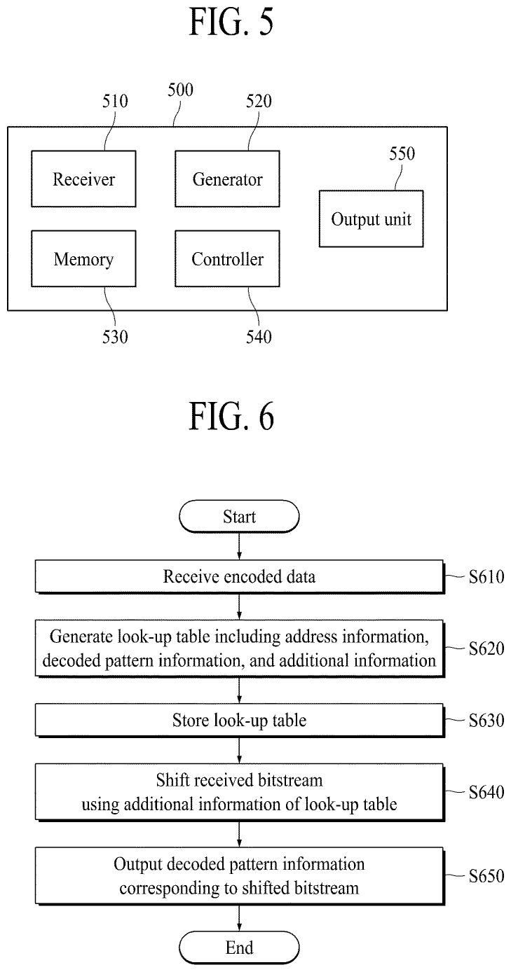

FIG. 5 is a block diagram including main components of an apparatus according to an embodiment of the present invention.

An apparatus 500 shown in FIG. 5 according to the embodiment of the present invention may use a variable-length code algorithm (for example, a Huffman code, a canonical Huffman code, and the like).

Furthermore, the apparatus 500 according to the embodiment of the present invention includes a receiver 510, a generator 520, a memory 530, a controller 540, and an output unit 550. These components are merely provided for the convenience of description, and the scope of the present invention is defined by the claims. Accordingly, those skilled in the art may omit, add, or modify some of the components shown in FIG. 5.

The receiver 510 receives encoded data from an external source.

The generator 520 generates a look-up table including address information mapped to the received encoded data, decoded pattern information, and additional information.

The memory 530 stores the generated look-up table.

The controller 540 shifts a received bitstream using the additional information of the look-up table stored in the memory 530.

In addition, the output unit 550 is able to output, without delay, decoded pattern information corresponding to the shifted bitstream in every cycle.

Here, the additional information corresponds, for example, to length information indicating the number of valid data bits in the bitstream. More specifically, the additional information corresponds to the “Length” information shown in FIG. 4. In the conventional technology, since the look-up table does not include the “Length” information, a serious drawback arises in that the decoding cycle becomes longer.

Meanwhile, according to another embodiment of the present invention, the generator 520 may generate a plurality of look-up tables. More detailed embodiments relating to this configuration will be described below with reference to FIGS. 8 to 10.

Furthermore, the generator 520 pads zeros at the front of the list of all data converted into the Huffman codes such that the data is aligned to have the same specific bit length. In addition, the generator 520 then divides the list of data aligned to have the same specific bit length into two groups based on a specific criterion.

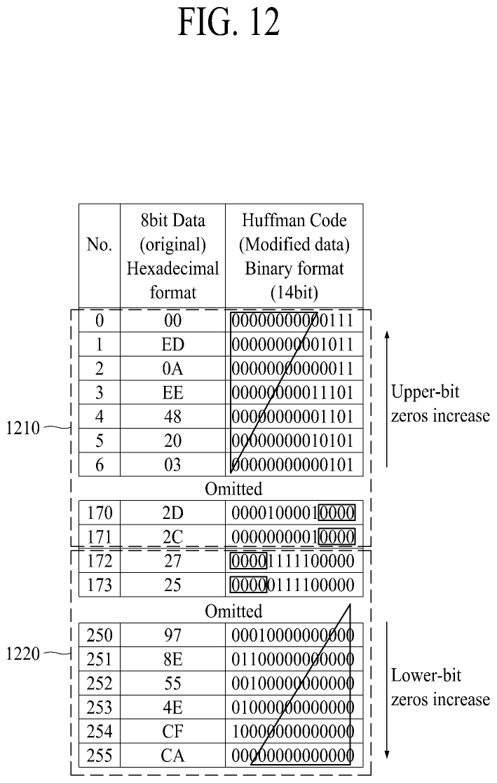

Here, the specific criterion corresponds, for example, to a case in which, in the list of data aligned to have the same specific bit length, the number of zeros in the upper bits is equal to the number of zeros in the lower bits. More detailed embodiments related to this will be described below with reference to FIGS. 11A to 11C and FIG. 12.

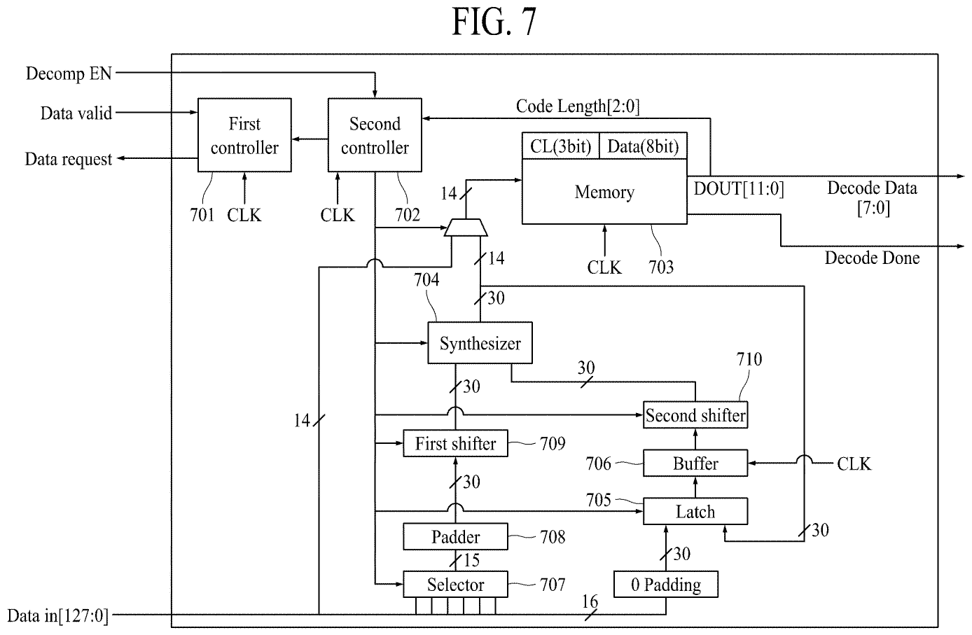

FIG. 6 is a flowchart illustrating a method of controlling an apparatus according to an embodiment of the present invention.

An apparatus according to an embodiment of the present invention (for example, an apparatus using a variable-length code algorithm) receives encoded data from the outside (S610) and generates a look-up table including address information mapped to the received encoded data, decoded pattern information, and additional information (S620).

The apparatus stores the generated look-up table in a memory (S630), shifts the received bitstream using the additional information of the look-up table stored in the memory (S640), and outputs the decoded pattern information corresponding to the shifted bitstream (S650).

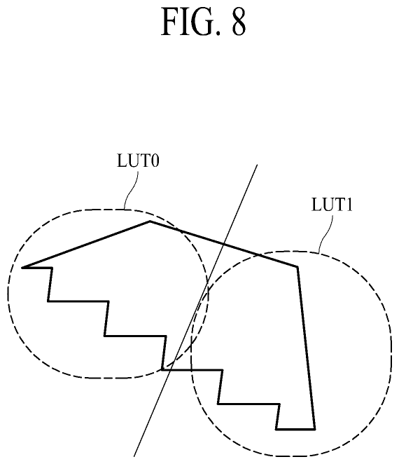

FIG. 7 is a diagram showing the block diagram shown in FIG. 5 in more detail.

A first controller 701 is a component required for communication with an external device.

A second controller 702 controls a first shifter 709, a second shifter 710, and a synthesizer 704 based on the number of bits remaining in a latch 705 and code length information supplied from a memory 703, and when data is needed, requests new data from the outside through the first controller 701. Here, the first shifter 709 and the second shifter 710 correspond, for example, to barrel shifters.

The latch 705 is a component configured to latch an incoming data input.

The first shifter 709 and the second shifter 710 perform barrel-shifting operations on a buffer 706 and subsequent data based on control information received from the second controller 702.

The synthesizer 704 merges the barrel-shifted data and inputs the merged data into the look-up table.

The memory 703 may be configured, for example, as a read-only memory (ROM), a static random access memory (SRAM), or a combination logic (Combi-Logic) structure.

More specifically, for example, an incoming data input set of L bits (e.g., 128 bits) is split into H-bit segments (e.g., 16 bits), in which H is a factor of L. When the number of bits remaining in the buffer 706 becomes less than or equal to M bits (e.g., 30 bits), new H-bit data is selected to update the buffer 706.

The first controller 701 transmits and receives valid/request information related to data input to and from an external apparatus.

The first shifter 709 and the second shifter 710 serve to shift the buffer 706 to the LSB through calculations of the length information output from the look-up table.

The newly input H-bit data is barrel-shifted and merged with the output data from the buffer 706.

For convenience of understanding, the operations of the components shown in FIG. 7 will be described in chronological order.

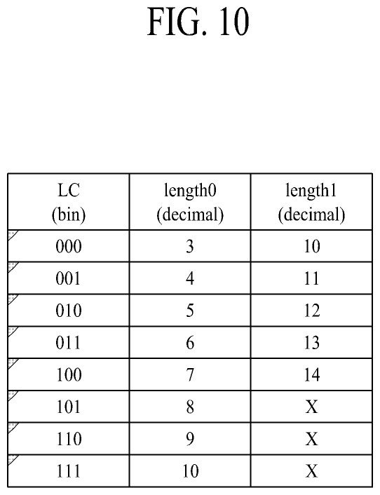

The decoder according to an embodiment of the present invention, as illustrated in FIG. 9, receives valid data 1 and 128-bit input data 1-1 from an external source through the first controller 701.

The latch 705 latches the output of the synthesizer 704.

A selector 707, according to a request from the second controller 702, selects the lower 16 bits from the total 128-bit input data, and inputs the selected bits to the first shifter 709.

The first shifter 709 performs barrel-shifting on the padded output of the selector 707 according to information calculated by the second controller 702 and transmits the result to the synthesizer 704.

The second shifter 710 performs barrel-shifting on the output of the latch 705 under the control of the second controller 702 and transmits the result to the synthesizer 704, in which the shifting is performed using code length information.

The synthesizer 704, under the control of the second controller 702, selects data from the first shifter 709 and the second shifter 710, forms new 30-bit data, transmits the 30-bit data to the latch 705, and transmits the lower 14 bits of the 30-bit data to the memory 703 as an address.

When the number of available bits in the output of the second shifter 710 is smaller than 14 and new data input (Data_in) is required, the output of the first shifter 709 and the insufficient bits from the second shifter 710 are combined using zero-padding of the first shifter to form 30 bits.

In the VLC algorithm, a canonical Huffman tree is used, and the LSB of the LUT input address is regarded as the root node of the canonical Huffman tree.

In the next cycle, 8-bit decoded data for the input address and the valid code length (3 bits) among the input addresses are output, and the code length is transmitted to the second controller 702, while 8-bit decoded data and a “done” signal indicating that decoding is complete are transmitted outside the decoder.

The operation of the second controller 702 may largely be divided into two stages.

In the initial operation stage, when data input is received, the second controller 702 directly inputs the lower 14 bits 1-2 of the lowest 16 bits into the memory 703, while inputting all 16 bits to the latch 705 to latch them in the buffer 706.

From the next cycle, the second controller 702 updates the bit counter remaining in the latch 705 within the second controller 702 every cycle and subtracts the bit count based on the code length information, which is the output of the memory 703.

In a cycle in which the second controller 702 receives the output of the memory 703, when the number of remaining bits in buffer 706 [29:0] becomes 14 or less, the second controller 702 controls the selector 707 to select the next 16 bits, performs barrel-shifting on the outputs of the selector 707 and the latch 705, and controls the synthesizer 704 to prepare next data to be input to the latch 705 and the memory 703 such that the data is input to the memory 703. At the same time, 16 is added to the bit counter.

In a cycle in which the second controller 702 receives the output of the memory 703, when the number of remaining bits in buffer 706 is greater than 14, the second controller 702 inputs data output through the second shifter 710 into the memory 703.

Meanwhile, according to another embodiment of the present invention, the look-up table in the memory 703 shown in FIG. 7 may be split into a plurality of parts and stored separately, which will be described with reference to FIGS. 8 and 3 below.

FIG. 8 is a diagram illustrating a process of separating a look-up table into two according to another embodiment of the present invention.

For example, a single look-up table having an address input of M bits (e.g., 14 bits, 16K) and data of D bits (e.g., 12 bits) may be divided as follows:

A first look-up table LUT0 having an address input of M1 bits (e.g., 10 bits, 1K) and data of D1 bits (e.g., 11 bits from the LSB), and a second look-up table LUT1 having an address input of M2 bits (e.g., 9 bits, 0.5K) and data of D2 bits (e.g., 11 bits) may be configured to be separated.

When implemented as described above, the size of the M-bit look-up table is 16K×12 bits (24 KB), whereas the size of the M1-bit and M2-bit look-up tables totals 1.5K×11 bits (2.0625 KB), achieving a significant technical effect of reducing the total size by approximately 91.4%.

When applying a VLC tree algorithm (for example, a canonical Huffman algorithm), according to an embodiment of the present disclosure, the root node of the tree is mapped to the LSB of the memory address, and the next-level nodes of the tree are mapped in the direction from the LSB toward the MSB.

Examining the memory map of an M-bit look-up table to which a canonical Huffman tree is applied shows that, compared to addresses in which shorter codes (e.g., Huffman codes corresponding to No. 0 through No. 11 in FIG. 11B) are mapped, addresses in which longer codes (e.g., Huffman codes corresponding to No. 250 through No. 255 in FIG. 11B) are mapped are padded with specific values closer to the LSB as the code length increases.

For this reason, for longer codes, a memory of M2 bits (e.g., 9 bits) from the MSB) may be configured by excluding the lower padded bits.

Also, when configuring a look-up table with shorter codes, a look-up table may be generated using only a memory of M1 bits (e.g., 10 bits from the LSB) without requiring the entire M-bit maximum length.

As described above, the first look-up table LUT0 and the second look-up table LUT1 are configured, and at addresses in the first look-up table LUT0 corresponding to the lower padded bits (e.g., addresses in which all 5 LSB bits from the LSB are zero), a pattern that may appear only in the second look-up table LUT1 (e.g., a pattern 0xCA with length 14) is stored.

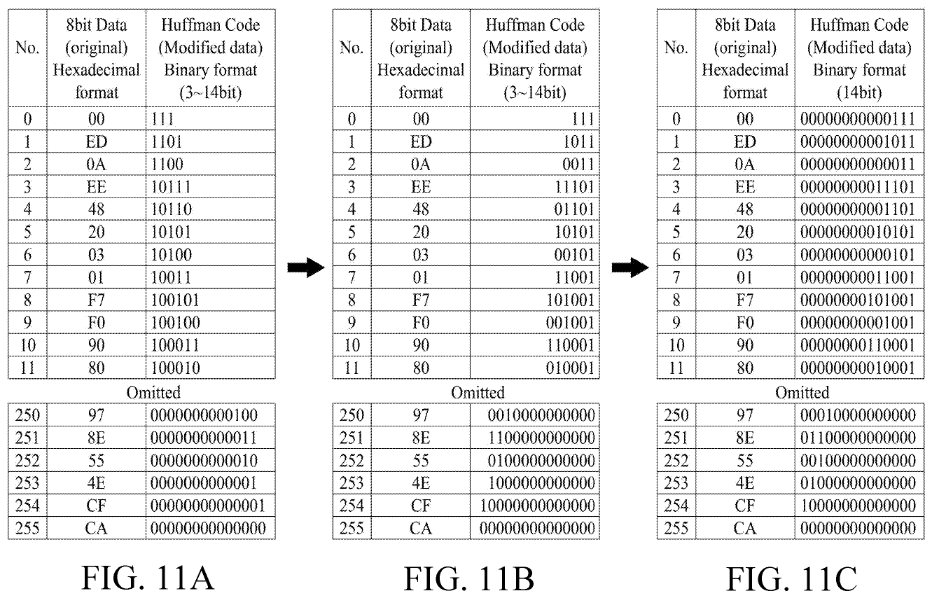

FIG. 9 is a block diagram illustrating a memory shown in FIG. 7 in more detail according to another embodiment of the present invention. FIG. 10 illustrates length tables of a plurality of look-up tables according to another embodiment of the present invention.

When the first look-up table LUT0 and the second look-up table LUT1 (refer to FIG. 8) are configured as described above and M bits (e.g., 14 bits) of address input are input to the two look-up tables, the lower M1 bits (e.g., 10 bits from the LSB) are input to the first look-up table LUT0, and the upper M2 bits (e.g., 9 bits from the MSB) are input to the second look-up able LUT1 simultaneously.

When a pattern (e.g., 0xCA) present in the second look-up table LUT1 is output from the first look-up table LUT0, it is determined that the decoding pattern for the input M-bit code is present in the second look-up table LUT1 (for example, 950 in FIG. 9), and the pattern and length information output from the second look-up table 920 shown in FIG. 9 are then selected and output externally.

When a pattern (e.g., 0xCA) present in the second look-up table LUT1 is not output from the first look-up table LUT0, it is determined that the decoding pattern for the input M-bit code is present in the second look-up table LUT0 (e.g., 950 in FIG. 9), and the pattern and length information output from the first look-up table 910 shown in FIG. 9 are selected and output externally.

Both the first look-up table LUT0 and the second look-up table LUT1 store length information, similar to that in an M-bit look-up table. However, when the table is split into two, because there are a total of eight length entries in the first look-up table LUT0 and a total of five length entries in the second look-up table LUT1, fewer bits (e.g., 3 bits) are required than when using a single look-up table. Therefore, codes corresponding to the length information are stored in the bits, and mapping information of length codes (LC) mapped to the first look-up table LUT0 and the second look-up table LUT1 is, for example, as shown in FIG. 10.

The length information output from the first look-up table 910 and the second look-up table 920 is decoded through the first decoder 930 and the second decoder 940 according to the table shown in FIG. 10, and output as “length information” shown in FIG. 9.

That is, when a single M-bit look-up table is split into an M1-bit first look-up table LUT0 and an M2-bit second look-up table LUT1, there is a technical effect of drastically minimizing the area of the look-up table in a specific VLC algorithm, thereby improving memory efficiency.

FIGS. 11A to 11C and FIG. 12 are diagrams illustrating a process of generating a plurality of look-up tables, according to another embodiment of the present invention.

Referring to FIGS. 11A to 11C and FIG. 12, a process of converting a look-up table generated using Huffman codes into a look-up table according to an embodiment of the present invention will be described. For convenience of description, an example in which 8-bit data is converted into canonical Huffman codes is provided.

The 256 generated look-up tables are arranged in order from the shortest to the longest Huffman code length (however, if 4-bit data is used, there are 16 LUTs).

The minimum and maximum values of the codes are checked. For example, as shown in FIG. 11A, the minimum code length is 3 bits, and the maximum code length is 14 bits.

The bits of the code, from LSB to MSB, are rearranged in the LSB-first order.

For example, the code [13:0] is changed to [0:13]. More specifically, as shown in FIG. 11B, the value “1101” is changed to “1011.”

Next, the front is padded with zeros to match the maximum length of 14 bits. For example, as illustrated in FIG. 11C, the value “1011” is changed to “00000000001011,” and the value “1010110” is changed to “00000001010110.”

The above described process is repeated for all 256 data items, from 0 to 255.

Meanwhile, according to another embodiment of the invention, an intermediate region needs to be determined to divide the look-up table into two.

Among the 14-bit addresses, there are 256 actual data entries. Analyzing the data reveals that both the upper and lower address regions are filled with zeros, and that the lower address region 1210 has an increasing number of zeros toward the higher bits, while the higher address region 1220 has an increasing number of zeros toward the lower bits.

As shown in the table of FIG. 12, the look-up table is split at a point at which the number of upper zeros and the number of lower zeros become equal, and as close as possible to ½ of the total data (midpoint) (e.g., 4 zeros for 14 bits).

However, in the table of FIG. 12, although No. 128 is the midpoint, the numbers of upper and lower zeros are unbalanced (4 and 3, respectively), and thus look-up table is split at No. 171 and No. 172 in which the number of lower zeros changes from 4 to 5.

From No. 0 to No. 171, the upper zeros are discarded, and a first look-up table LUT0 is generated with 10-bit addresses.

Then, from No. 172 to No. 255, the lower zeros are discarded, and a second look-up table LUT1 is generated with 9-bit addresses.

The count value of valid bits in the address is changed (for example, reducing 4 bits to 3 bits).

Since the first look-up table LUT0 has a valid address count ranging from 3 to 10, 3 bits are allocated to transform the values as 3-000, 4-001, . . . , 9-110, and 10-111.

Since the second look-up table LUT1 has a valid address count ranging from 10 to 14, 3 bits are allocated to transform the values as 10-000, 11-001, . . . , and 14-100 while the remainder is not used.

Then, as shown in Table 1 below, the valid length (Length) is transformed into len_code.

TABLE 1

| Length idx | length0 | len_code | length1 | len_code |
|---|---|---|---|---|
| 0 | 3 | 000 | 10 | 000 |
| 1 | 4 | 001 | 11 | 001 |
| 2 | 5 | 010 | 12 | 010 |
| 3 | 6 | 011 | 13 | 011 |
| 4 | 7 | 100 | 14 | 100 |
| 5 | 8 | 101 | X | 101 |
| 6 | 9 | 110 | X | 110 |
| 7 | 10 | 111 | X | 111 |

For example, data may be configured as 11 bits (length code (3 bits)+original data (8 bits)) and matched to an address.

For address regions that do not correspond to a valid length, the same original data is matched such that data is present throughout the entire memory space, thereby generating the first look-up table LUT0/the second look-up table LUT1.

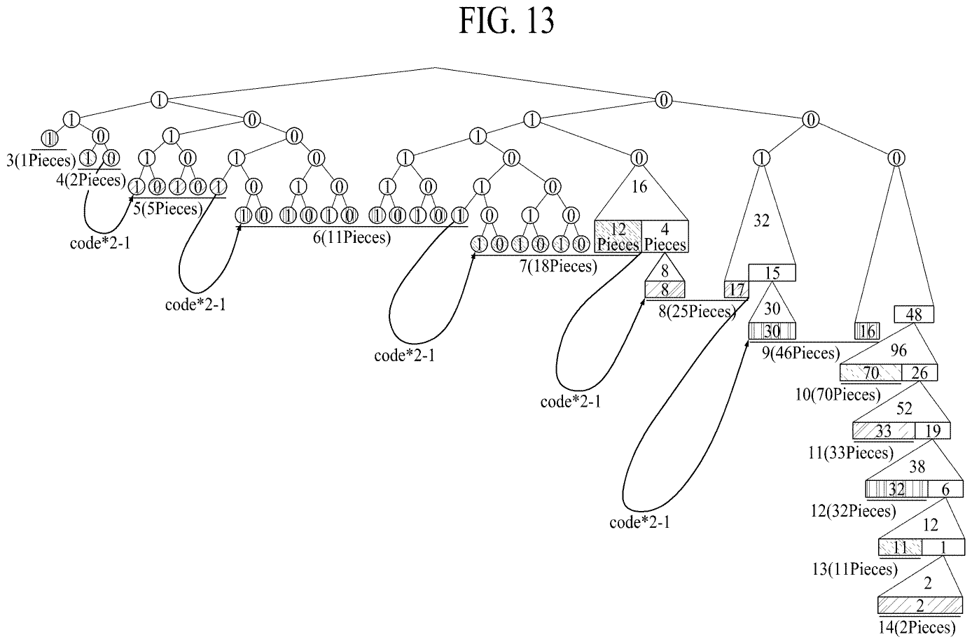

FIG. 13 is a diagram illustrating the structure of a canonical Huffman tree used in a decoder according to an embodiment of the present invention.

As shown in FIG. 13, an embodiment of the canonical Huffman tree applicable to the present invention is as follows:
Minimum code length: 3
Maximum code length: 14
Number of decoded patterns: 256
Decoded pattern range: 0x00 to 0xFF

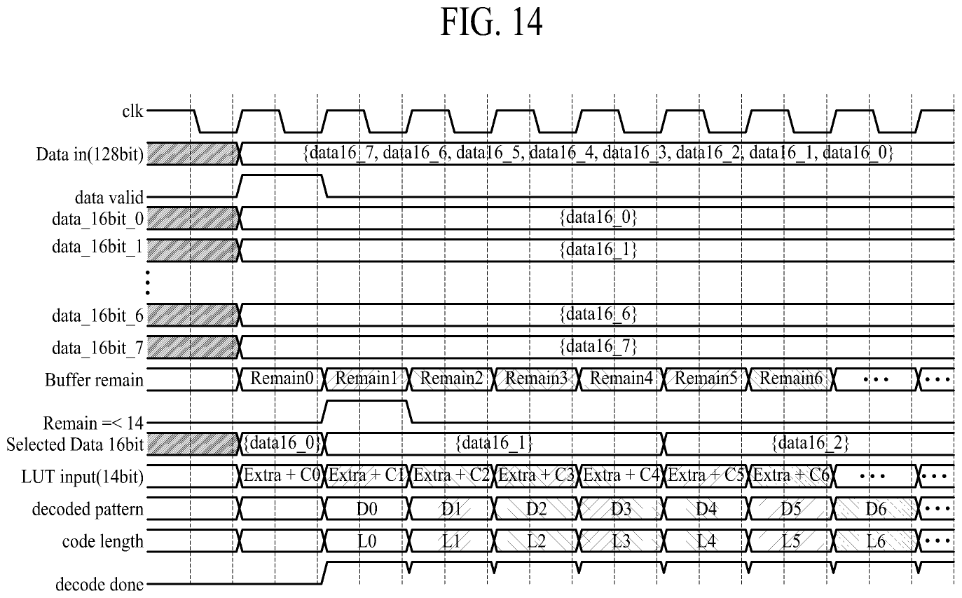

FIG. 14 is a timing diagram illustrating a decoding operation of a decoder according to an embodiment of the present invention.

When Data input and data Valid are first input, the 128-bit data input is divided into eight 16-bit segments and connected to the selector 707.

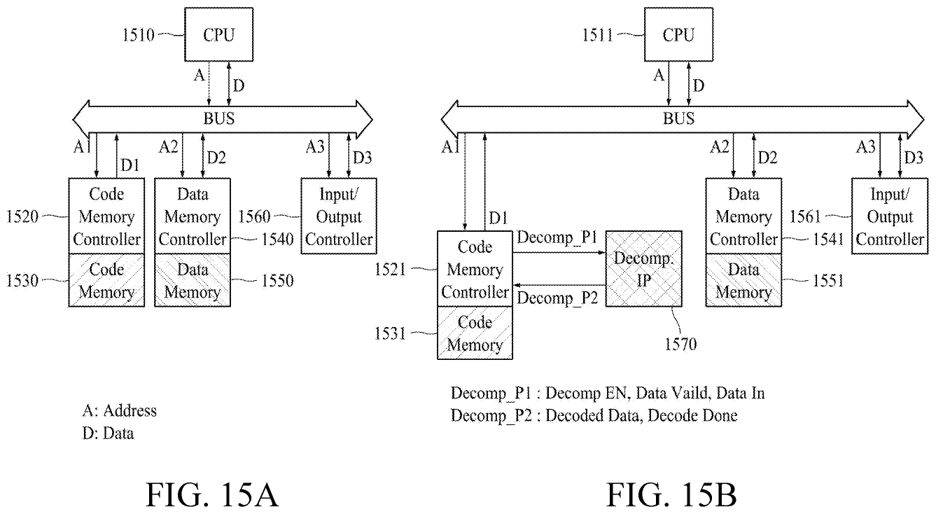

Meanwhile, Data input, Data valid, Decode_data, and Decode_done shown in FIG. 14 will be described in more detail below with reference to FIGS. 15A and 15B.

In the cycle in which the initial Data_valid is High, the lower 14 bits within data_16bit_0 are input to the LUT. Within the 14 bits, a Code C0 having a code length of L0 is included in the lower portion, and the remaining bits are input above it. When all 14 bits are input to the LUT, the decoded pattern and code length information are output in the next cycle.

Through the output code length L0, the LUT input is updated, and in this case, among the lower bits, there is C1 having a code length of L1 and the remaining bits.

When the number of remaining bits in the buffer is 14 or less, the next 16-bit data among data_16bit_0 to data_16bit_7 is selected and reflected in the LUT input and decoding is performed.

Due to such a structure, there is a technical effect that data decoding is performed every cycle after the initial Data input is received.

FIGS. 15A and 15B are diagrams for comparing an MCU according to the conventional technology and an MCU to which the decoder according to an embodiment of the present invention is applied.

As shown in FIG. 15A, an MCU according to the conventional technology includes: a CPU 1510, a code memory 1530 that stores software, a data memory 1550 that stores temporary data generated during CPU operation, an input/output controller 1560 for transmitting and receiving signals to and from the external system according to software operation, a code memory controller 1520, a data memory controller 1540, and a BUS interconnecting each internal block.

In contrast, as shown in FIG. 15B, the MCU according to an embodiment of the present invention includes a CPU 1511, a code memory controller 1521, a code memory 1531, a data memory controller 1541, a data memory 1551, an input/output controller 1561, and a decoder 1570.

In particular, the decoder 1570 according to an embodiment of the present embodiment connects to the code memory controller 1521 to store compressed software in the code memory 1531, decodes the software, and transmits the software to the CPU 1511.

Furthermore, according to a Decomp_P1 signal from the code memory 1531, the decoder 1570 performs Decomp_EN (decode operation control), Data Valid (signal indicating data ready for transmission), and Data_IN (compressed data read from the code memory) operations, and when decoded data is ready, the decoder 1570 transmits data (such as Decoded_Data (decoded data) and Decode_Done (decoding complete)) to the code memory controller 1521 via the Decomp_P2 signal.

The decoded data is then transmitted to the CPU 1511 through the data path and BUS path.

According to an embodiment of the present invention, the decoding speed for compressed codes can be increased, thereby improving the overall processing speed of the system. Furthermore, through a memory map configuration different from that of the conventional technology, a high-speed variable-length lossless code decoder can be implemented.

For reference, in a microcontroller unit (MCU), a flash memory is mainly used as a memory for storing codes and data. Due to the characteristics of the MCU chip, a flash memory often occupies 50% or more of the total chip area.

Accordingly, when codes are stored in a compressed form in the actual flash memory, the same codes and data can be stored in a smaller flash memory.

This can lead to a reduction in the MCU chip size and an improvement in mass productivity.

In addition, when compressed codes are stored in the flash memory and decoded in parallel using a high-speed decoder proposed in the present invention and then the decoded data is stored in a cache memory or the like, it is possible to maintain system performance while reducing chip size, thereby increasing profitability as a secondary effect.

The effects of the present invention are not limited to those described above, and other effects that are not described above will be clearly understood by those skilled in the art from the above detailed description and drawings.

What is claimed is:

1. A method of controlling an apparatus using a variable-length code algorithm, comprising:
receiving encoded data from an external device;
generating a look-up table including address information mapped to the received encoded data, decoded pattern information, and additional information; and
storing the generated look-up table in a memory.

2. The method of claim 1, further comprising:
shifting an incoming bitstream using the additional information of the look-up table stored in the memory; and
outputting decoded pattern information corresponding to the shifted bitstream.

3. The method of claim 2, wherein the additional information corresponds to length information indicating a number of valid data items in the bitstream.

4. The method of claim 1, wherein the generating of the look-up table further includes generating a plurality of look-up tables.

5. The method of claim 4, wherein the generating of the plurality of look-up tables further includes padding zeros at a front of a list of all data transformed into Huffman codes such that the data is aligned to have the same specific bit length.

6. The method of claim 5, further comprising dividing the list of data aligned to have the same specific bit length into two groups based on a specific criterion.

7. The method of claim 6, wherein the specific criterion corresponds to a case in which, in the list of data aligned to have the same specific bit length, a number of zeros in upper bits is equal to a number of zeros in lower bits.

8. An apparatus using a variable-length code algorithm, comprising:
a receiver that receives encoded data from an external device;
a generator that generates a look-up table including address information mapped to the received encoded data, decoded pattern information, and additional information; and
a memory that stores the generated look-up table.

9. The apparatus of claim 8, further comprising:
a controller that shifts an incoming bitstream using the additional information of the look-up table stored in the memory; and
an output unit that outputs decoded pattern information corresponding to the shifted bitstream.

10. The apparatus of claim 9, wherein the additional information corresponds to length information indicating a number of valid data items in the bitstream.

11. The apparatus of claim 9, wherein the generator generates a plurality of look-up tables.

12. The apparatus of claim 11, wherein the generator pads zeros at a front of a list of all data transformed into Huffman codes such that the data is aligned to have the same specific bit length.

13. The apparatus of claim 12, wherein the generator divides the list of data aligned to have the same specific bit length into two groups based on a specific criterion.

14. The apparatus of claim 13, wherein the specific criterion corresponds to a case in which, in the list of data aligned to have the same specific bit length, a number of zeros in upper bits is equal to a number of zeros in lower bits.
